(19) United States
(12) Patent Application Publication
(10) Pub. No.: US 2006/0113624 A1
(43) Pub. Date: Jun. 1, 2006

(54) LOCOS-based Schottky barrier diode and its manufacturing methods

(75) Inventor: Ching-Yuan Wu, Hsinchu City (TW)

Correspondence Address: DENNISON, SCHULTZ, DOUGHERTY & MACDONALD, 1727 KING STREET, SUITE 105, ALEXANDRIA, VA, 22314, US

(73) Assignee: SILICON-BASED TECHNOLOGY CORP.

(21) Appl. No.: 10/997,956

(22) Filed: Nov. 29, 2004

(51) Int. Cl. H01L 29/47

(52) U.S. Cl. 257/471; 257/155; 257/484

(57) ABSTRACT

The LOCOS-based Schottky barrier diode of the present invention comprises a raised diffusion guard ring surrounded by an outer LOCOS field oxide layer, a recessed semiconductor substrate with or without a compensated diffusion layer surrounded by the raised diffusion guard ring, a metal silicide layer formed over a portion of the raised diffusion guard ring and the recessed semiconductor substrate, and a patterned metal layer formed at least over the metal silicide layer, wherein the raised diffusion guard ring is formed between an inner LOCOS field oxide layer and the outer LOCOS field oxide layer and the recessed semiconductor substrate is formed by removing the inner LOCOS field oxide layer. The LOCOS-based Schottky barrier diode comprises the raised diffusion guard ring to reduce junction curvature effect on reverse breakdown voltage, the recessed semiconductor substrate to reduce forward voltage, and the compensated diffusion layer to reduce reverse leakage current.

### BACKGROUND OF THE INVENTION

1. Field of the Invention

The present invention relates generally to a Schottky barrier diode and its manufacturing method and, more particularly, to a LOCOS-based Schottky barrier diode (LBSBD) and its manufacturing methods.

2. Description of the Related Art

A Schottky barrier diode comprising a metal-semiconductor contact is known to be a majority-carrier device and is therefore used as a high-speed switching diode or a high-frequency rectifier. For a Schottky barrier diode used as a power switching diode, the major design issues are concentrated on reverse breakdown voltage (V_{B}), reverse leakage current (I_{R}), forward current (I_{f}) and forward voltage (V_{f}). In general, a diffusion guard ring is required to reduce the reverse leakage current due to edge effect of the metal-semiconductor contact and to relax soft breakdown due to high edge field. However, the diffusion guard ring may produce junction curvature effect on the reverse breakdown voltage and a deeper junction depth of the diffusion guard ring is in general required to reduce junction curvature effect. As a consequence, it is difficult to simultaneously obtain a higher reverse breakdown voltage and a lower forward voltage (V_{f}) for a given metal-semiconductor contact area.

FIG. 1 shows a schematic cross-sectional view of a conventional Schottky barrier diode with a diffusion guard ring, in which a p⁺ diffusion guard ring 105 is formed in a surface portion of a n⁻/n⁺ epitaxial silicon substrate 101/100 through a diffusion window (not shown) formed between two patterned field oxide layers 102a; a metal silicide layer 103 being acted as a Schottky barrier metal is formed on a portion of the p⁺ diffusion guard ring 105 and the n⁻/n⁺ epitaxial silicon substrate 101/100 surrounded by a patterned step borosilicate glass (BSG) layer 106a; a patterned metal layer 104a is formed on a portion of the patterned field oxide layer 102a, the patterned step borosilicate glass layer 106a, and the metal silicide layer 103; and a backside metal layer (not shown) being acted as an ohmic contact metal is formed on the n⁺ silicon substrate 100.

From FIG. 1, it is clearly seen that three masking photoresist steps are required to implement the Schottky barrier diode, wherein a first masking photoresist step is used to define a diffusion window for forming the p⁺ diffusion guard ring 105; a second masking photoresist step is used to remove the patterned field oxide layer 102a (not shown) and a portion of the step borosilicate glass layer 106a (not shown) for forming the metal silicide layer 103; and a third masking photoresist step is used to form the patterned metal layer 104a. Apparently, a width of the p⁺ diffusion guard ring 105 must be kept to be larger and a junction depth of the p⁺ diffusion guard ring 105 must be kept to be deeper. As a consequence, the cell size of the prior art is larger and the forward voltage (V_{f}) for a given forward current (I_{f}) is also larger. Moreover, the step coverage for the patterned metal layer 104a is poor.

It is therefore a major objective of the present invention to offer a LOCOS-based Schottky barrier diode with a raised diffusion guard ring for obtaining higher reverse breakdown voltage and a recessed semiconductor substrate to give lower forward voltage.

It is another objective of the present invention to offer a LOCOS-based Schottky barrier diode with a better metal step coverage.

It is an important objective of the present invention to offer a LOCOS-based Schottky barrier diode with a compensated diffusion layer being formed in a surface portion of the recessed semiconductor substrate to reduce reverse leakage current due to image-force lowering and to further increase reverse breakdown voltage through reducing junction curvature effect of the raised diffusion guard ring.

### SUMMARY OF THE INVENTION

The present invention discloses a LOCOS-based Schottky barrier diode and its manufacturing methods. The LOCOS-based Schottky barrier diode of the present invention comprises a semiconductor substrate of a first conductivity type being comprised of a lightly-doped epitaxial silicon layer formed on a heavily-doped silicon substrate, a raised diffusion guard ring of a second conductivity type being formed between an outer LOCOS field oxide layer and an inner LOCOS field oxide layer, a recessed semiconductor substrate with or without a compensated diffusion layer being surrounded by the raised diffusion guard ring, a metal silicide layer being formed over a semiconductor surface including a portion of the raised diffusion guard ring and the recessed semiconductor substrate surrounded by the raised diffusion guard ring, and a patterned metal layer being at least formed over the metal silicide layer, wherein the compensated diffusion layer is formed in a surface portion of the recessed semiconductor substrate by implanting a compensated dose of doping impurities across a pad oxide layer before performing a local oxidation of silicon process and the inner LOCOS field oxide layer is removed through a masking photoresist step after performing a diffusion process to form the raised diffusion guard ring. The LOCOS-based Schottky barrier diode of the present invention offers the raised diffusion guard ring to reduce junction curvature effect on reverse breakdown voltage, the recessed semiconductor substrate for forming a Schottky barrier contact to reduce parasitic series resistance, and the compensated diffusion layer in a surface portion of the recessed semiconductor substrate to reduce reverse leakage current due to image-force lowering effect and to further reduce the junction curvature effect of the raised diffusion guard ring.

### BRIEF DESCRIPTION OF THE DRAWINGS

FIG. 1 shows a schematic cross-sectional view of a Schottky barrier contact structure of the prior art.

FIG. 2A through FIG. 2G show process steps and their schematic cross-sectional views of fabricating a first-type LOCOS-based Schottky barrier diode of the present invention.

FIG. 3A through FIG. 3F show process steps after FIG. 2B and their schematic cross-sectional views of fabricating a second-type LOCOS-based Schottky barrier diode of the present invention.

FIG. 4A and FIG. 4B show simplified process steps after FIG. 2E and their schematic cross-sectional views of fabricating a third-type LOCOS-based Schottky barrier diode of the present invention.

FIG. 5A and FIG. 5B show simplified process steps after FIG. 3D and their schematic cross-sectional views of fabricating a fourth-type LOCOS-based Schottky barrier diode of the present invention.

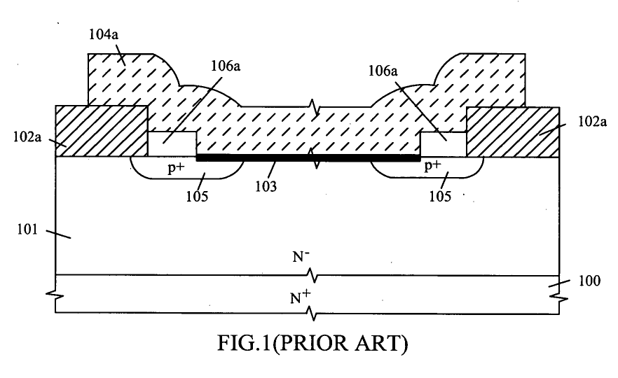

### DETAILED DESCRIPTION OF THE PREFERRED EMBODIMENTS

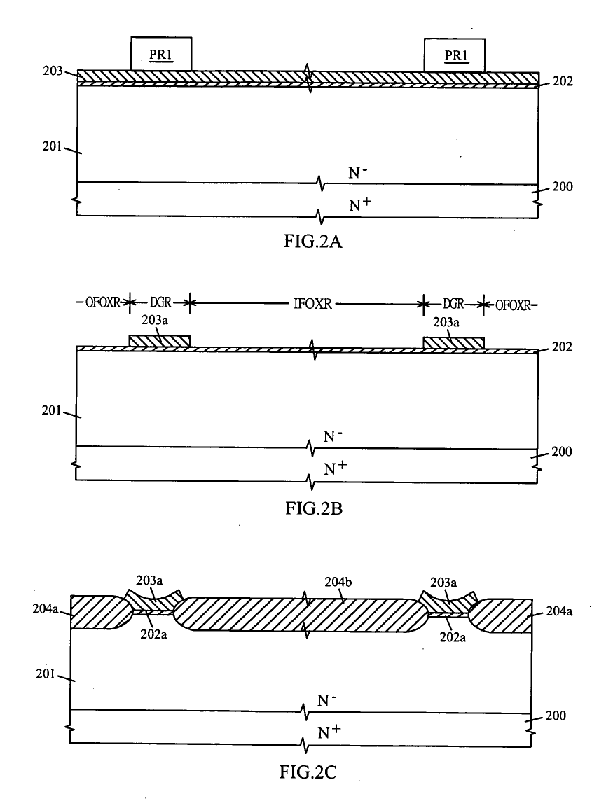

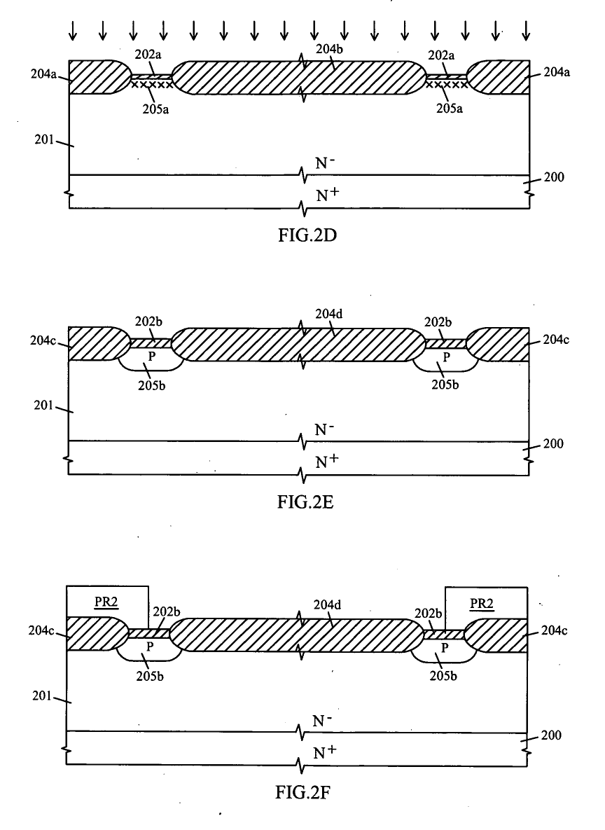

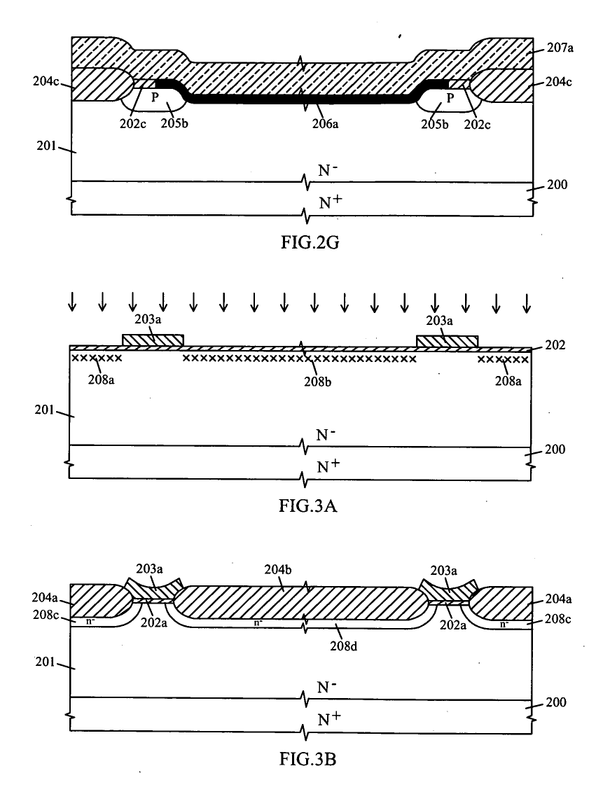

Referring now to FIG. 2A through FIG. 2G, there are shown process steps and their schematic cross-sectional views of fabricating a first-type LOCOS-based Schottky barrier diode of the present invention.

FIG. 2A shows that a pad oxide layer 202 is formed on a semiconductor substrate 201/200 of a first conductivity type; a masking silicon nitride layer 203 is then formed on the pad oxide layer 202; and subsequently, a first masking photoresist (PR1) step is performed to define a diffusion guard ring region (DGR). The pad oxide layer 202 is a thermal silicon dioxide layer grown on the semiconductor substrate 201/200 in a dry oxygen ambient and its thickness is preferably between 100 Angstroms and 500 Angstroms. The masking silicon nitride layer 203 is formed by low-pressure chemical vapor deposition (LPCVD) and its thickness is preferably between 500 Angstroms and 1500 Angstroms. The semiconductor substrate 201/200 comprises a lightly-doped epitaxial silicon layer 201 being formed on a heavily-doped silicon substrate 200, in which the lightly-doped epitaxial silicon layer 201 has a thickness between 2 μm and 35 μm and a doping concentration between 10¹⁴/cm³ and 10¹⁷/cm³; the heavily-doped silicon substrate 200 has a doping concentration between 10¹⁸/cm³ and 5×10²⁰/cm³ and a thickness between 250 μm and 800 μm, depending on wafer size.

FIG. 2B shows that the masking silicon nitride layer 203 outside of the diffusion guard ring region (DGR) is removed by anisotropic dry etching to form an inner field oxide region (IFOXR) and an outer field oxide region (OFOXR) and, therefore, the patterned masking silicon nitride layer 203a in the diffusion guard ring region (DGR) is remained.

FIG. 2C shows that the pad oxide layer 202 outside of the patterned masking silicon nitride layer 203a is removed by using buffered hydrofluoric acid or dilute hydrofluoric acid and a local oxidation of silicon (LOCOS) process is performed in a steam or wet oxygen ambient to form an inner LOCOS field oxide layer 204b in the inner field oxide region (IFOXR) and an outer LOCOS field oxide layer 204a in the outer field oxide region (OFOXR). The thickness of the inner/outer LOCOS field oxide layer 204b/204a is preferably between 6000 Angstroms and 10000 Angstroms and oxidation temperature is between 950° C. and 1200° C. It should be noted that the local oxidation of silicon process can be performed without removing the pad oxide layer 202 outside of the patterned masking silicon nitride layer 203a.

FIG. 2D shows that the patterned masking silicon nitride layer 203a is removed by using hot-phosphoric acid or anisotropic dry etching; and subsequently, ion implantation is performed in a self-aligned manner by implanting doping impurities of a second conductivity type across the patterned pad oxide layer 202a into a surface portion of the semiconductor substrate 201/200 to form an implantation region 205a. It should be noted that a conventional thermal diffusion process using a liquid source, a solid source or a gas source can be performed instead of ion implantation if the patterned pad oxide layer 202a is removed.

FIG. 2E shows that a drive-in process is performed to form a raised diffusion guard ring 205b; the outer/inner LOCOS field oxide layer 204a/204b and the patterned pad oxide layer 202a are simultaneously grown thicker. It should be emphasized that a junction depth of the raised diffusion guard ring 205b is controlled to be slightly larger than a bottom surface level of the outer/inner LOCOS field oxide layer 204c/204d. The raised diffusion guard ring 205b can be a heavily-doped diffusion guard ring, a moderately-doped diffusion guard ring or a heavily-doped diffusion guard ring formed within a moderately-doped diffusion guard ring.

FIG. 2F shows that a second masking photoresist (PR2) step is performed to cover the patterned second masking photoresist (PR2) on the outer LOCOS field oxide layer 204c and a portion of a thermal oxide layer 202b on the raised diffusion guard ring 205b.

FIG. 2G shows that the inner LOCOS field oxide layer 204d and the thermal oxide layer 202b outside of the patterned second masking photoresist (PR2) are removed by using buffered hydrofluoric acid; the patterned second masking photoresist (PR2) is then stripped and a wafer cleaning process is then performed; and subsequently, a metal suicide layer 206a is formed on an exposed silicon surface by using a well-known self-aligned silicidation process, including a portion of the raised diffusion guard ring 205b and a recessed semiconductor substrate 201/200 surrounded by the raised diffusion guard ring 205b. The metal silicide layer 206a is preferably a refractory metal silicide layer.

FIG. 2G also shows that a patterned metal layer 207a is formed on a portion of the outer LOCOS field oxide layer 204c and the metal silicide layer 206a by using a third masking photoresist (PR3) step (not shown). The patterned metal layer 207a comprises a metal layer on a barrier metal layer. The metal layer comprises aluminum (Al), silver (Ag) or gold (Au). The barrier metal layer comprises a refractory metal layer or a refractory metal nitride layer. It should be noted that the heavily-doped silicon substrate 200 is back-lapped (not shown) to a predetermined thickness in order to reduce parasitic series resistance and a backside ohmic contact is then performed (not shown).

Apparently, the features and advantages of the first-type LOCOS-based Schottky barrier diode of the present invention can be summarized below:
(a) The first-type LOCOS-based Schottky barrier diode of the present invention offers a raised diffusion guard ring to reduce the junction curvature effect on reverse breakdown voltage, so a higher reverse breakdown voltage can be easily obtained by using a smaller junction depth of the raised diffusion guard ring.
(b) The first-type LOCOS-based Schottky barrier diode of the present invention offers a recessed semiconductor substrate surrounded by the raised diffusion guard ring for forming a Schottky barrier metal contact to reduce the parasitic series resistance due to the lightly-doped epitaxial silicon layer for a given reverse breakdown voltage, so a lower forward voltage for a given forward current can be obtained without increasing cell area.
(c) The first-type LOCOS-based Schottky barrier diode of the present invention offers an outer LOCOS field oxide layer and a removed inner LOCOS field oxide layer to provide a much better metal step coverage.
(d) The first-type LOCOS-based Schottky barrier diode of the present invention offers a minimized cell area with a minimized raised diffusion guard ring and an optimized Schottky barrier contact area for given reverse breakdown voltage, forward voltage and forward current.

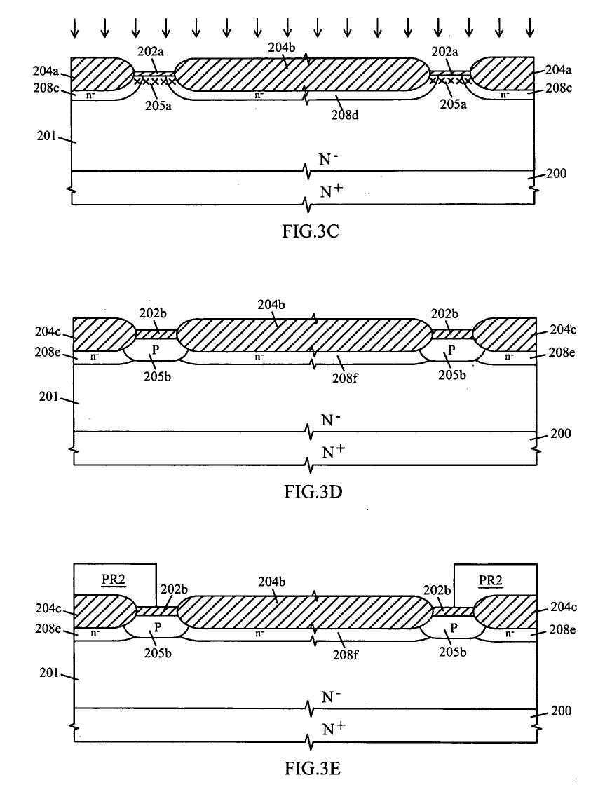

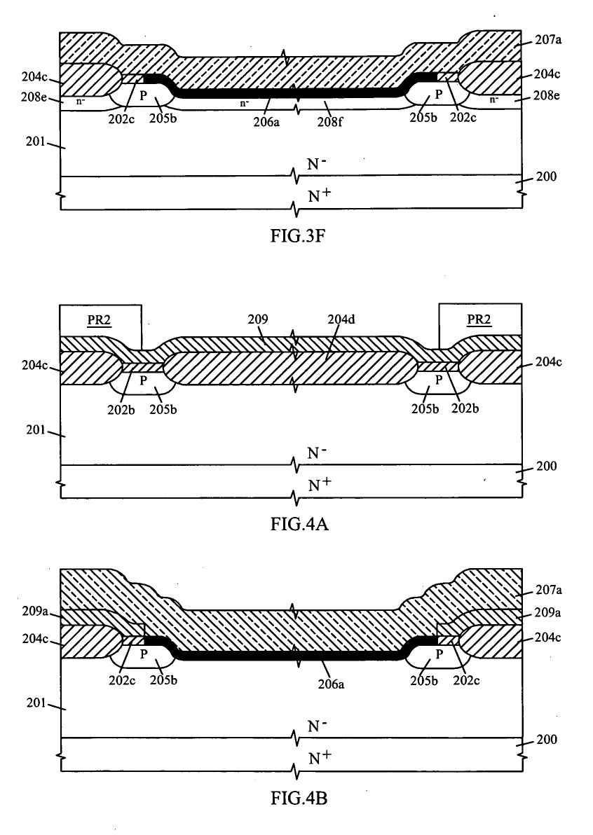

Referring now to FIG. 3A through FIG. 3F, there are shown process steps after FIG. 2B and their schematic cross-sectional views of fabricating a second-type LOCOS-based Schottky barrier diode of the present invention.

FIG. 3A shows that an implantation process is performed in a self-aligned manner to form compensated implant regions 208b/208a of the first conductivity type in surface portions of the lightly-doped epitaxial silicon layer 201 outside of the patterned masking silicon nitride layer 203a. The dose of compensated implantation is adjusted to have a peak doping concentration approximately equal to doping concentration in the lightly-doped epitaxial silicon layer 201.

FIG. 3B shows that a local oxidation of silicon process is performed to form an inner LOCOS field oxide layer 204b in the inner field oxide region (IFOXR) and an outer LOCOS field oxide layer 204a in the outer field oxide region (OFOXR), as described in FIG. 2C. It is clearly seen that the compensated implant region 208b/208a shown in FIG. 3A are simultaneously driven in to form the compensated diffusion layers 208d/208c of the first conductivity type.

FIG. 3C shows that the patterned masking silicon nitride layer 203a in the guard ring diffusion region (GDR) is removed by using hot-phosphoric acid or anisotropic dry etching and ion-implantation is then performed in a self-aligned manner as described in FIG. 2D.

FIG. 3D shows that a drive-in process is performed to form a raised diffusion guard ring 205b; and simultaneously, the patterned pad oxide layer 202a and the inner/outer LOCOS field oxide layer 204b/204a are grown thicker as described in FIG. 2E.

FIG. 3E shows that a second masking photoresist (PR2) step is performed to form a patterned second masking photoresist (PR2) over the outer LOCOS field oxide layer 204c and a portion of the thermal oxide layer 202b.

Following the process steps described in FIG. 2G, FIG. 3F can be easily obtained. From FIG. 3F, it is clearly seen that the compensated diffusion layer 208f under the metal silicide layer 206a with a lower doping concentration profile in a surface portion of the lightly-doped epitaxial silicon layer 201 may largely reduce the image-force lowering effect on the reverse leakage current of the second-type LOCOS-based Schottky barrier diode of the present invention. Moreover, it is clearly seen that the compensated diffusion layers 208f/208e may largely reduce the junction curvature effect of the raised diffusion guard ring 205b and a higher breakdown voltage can be easily obtained, as compared to FIG. 2G.

Referring now to FIG. 4A and FIG. 4B, there are shown simplified process steps after FIG. 2E and their schematic cross-sectional views of fabricating a third-type LOCOS-based Schottky barrier diode of the present invention.

FIG. 4A shows that a capping dielectric layer 209 is formed over a formed structure surface shown in FIG. 2E; and subsequently, a second masking photoresist (PR2) step is performed to define a metal contact for forming a metal silicide layer 206a and a termination region (not shown) under the patterned second mask photoresist (PR2). It should be noted that the termination region may comprise a plurality of raised floating diffusion rings (not shown) except the raised diffusion guard ring 205b. The capping dielectric layer 209 is preferably made of silicon nitride as deposited by LPCVD and its thickness is preferably between 500 Angstroms and 3000 Angstroms.

FIG. 4B shows that the capping dielectric layer 209 outside of the patterned second masking photoresist (PR2) is removed by anisotropic dry etching to form a patterned capping dielectric layer 209a; the thermal oxide layer 202b and the inner LOCOS field-oxide layer 204d outside of the patterned second masking photoresist (PR2) are then removed by using anisotropic dry etching or buffered hydrofluoric acid and, subsequently, the patterned second masking photoresist (PR2) are stripped; a self-aligned silicidation process is performed to form the metal silicide layer 206a over an exposed silicon surface in the metal contact region; and thereafter, a patterned metal layer 207a is formed over the metal silicide layer 206a and a portion of the patterned capping dielectric layer 209a.

From FIG. 4B, it is clearly seen that the patterned capping dielectric layer 209a not only acts as a hard masking layer for forming the metal silicide layer 206a but also acts as a passivation or protection layer. More importantly, the patterned capping dielectric layer 209a provides an etching stop layer for patterning a thick metal layer 207 (not shown), as compared to FIG. 2G.

Referring now to FIG. 5A and FIG. 5B, there are shown simplified process steps after FIG. 3D and their schematic cross-sectional views of fabricating a fourth-type LOCOS-based Schottky barrier diode of the present invention.

FIG. 5A shows that a capping dielectric layer 209 is formed over a formed structure surface shown in FIG. 3D and a second masking photoresist (PR2) step is performed, as described in FIG. 4A.

Following the same process steps as described in FIG. 4B, FIG. 5B can be easily obtained. Apparently, the advantages and features of the fourth-type LOCOS-based Schottky barrier diode are the same as those described in FIG. 4B, as compared to FIG. 3F.

Based on the above descriptions, the features and advantages of the LOCOS-based Schottky barrier diode of the present invention can be summarized below:
(a) The LOCOS-based Schottky barrier diode of the present invention offers a raised diffusion guard ring formed between an inner LOCOS field oxide layer and an outer LOCOS field oxide layer to reduce the junction curvature effect on the reverse breakdown voltage for the raised diffusion guard ring with a smaller junction depth.
(b) The LOCOS-based Schottky barrier diode of the present invention offers a recessed semiconductor surface in the lightly-doped epitaxial silicon layer for forming a Schottky barrier contact to reduce forward voltage.
(c) The LOCOS-based Schottky barrier diode of the present invention offers a compensated diffusion layer surrounded by the raised diffusion guard ring for forming the Schottky barrier contact to reduce the image-force lowering effect on the reverse leakage current and to simultaneously eliminate or reduce the junction curvature effect on the reverse breakdown voltage.
(d) The LOCOS-based Schottky barrier diode of the present invention offers a smooth surface to improve metal step coverage.
(e) The LOCOS-based Schottky barrier diode of the present invention offers a capping dielectric layer being acted as a hard masking layer for patterning the Schottky barrier contact region and the termination region and being simultaneously acted as a passivation or protection layer and an etching stop layer for patterning a thick metal layer.

It should be noted that the dopants implanted in the compensated implant regions 208a/208b are preferably boron impurities for the n⁻/n⁺ silicon substrate 201/200. It should be emphasized that the LOCOS-based Schottky barrier diodes as described can be easily extended to fabricate the LOCOS-based Schottky barrier diodes on the p⁻/p⁺ silicon substrate by changing doping types in the raised diffusion guard ring 205b and the compensated implant regions 208a/208b.

While the present invention has been particularly shown and described with a reference to the present examples and embodiments as considered as illustrative and not restrictive. Moreover, the present invention is not to be limited to the details given herein, it will be understood by those skilled in the art that various changes in forms and details may be made without departure from the true spirit and scope of the present invention

What is claimed is:

1. A LOCOS-based Schottky barrier diode, comprising:
a semiconductor substrate of a first conductivity type, wherein the semiconductor substrate comprises a lightly-doped epitaxial semiconductor layer being formed on a heavily-doped semiconductor substrate;
a raised diffusion guard ring of a second conductivity type being formed in the lightly-doped epitaxial semiconductor layer between an outer LOCOS field oxide layer and an inner LOCOS field oxide layer, wherein the inner LOCOS field oxide layer is removed to form a recessed semiconductor substrate surrounded by the raised diffusion guard ring; and
a metal suicide layer being formed over an inner portion of the raised diffusion guard ring surrounded by the outer LOCOS field oxide layer and the recessed semiconductor substrate surrounded by the raised diffusion guard ring.

2. The LOCOS-based Schottky barrier diode according to claim 1, wherein the outer and inner LOCOS field oxide layers are formed by a local oxidation of silicon (LOCOS) process in a steam or wet oxygen ambient.

3. The LOCOS-based Schottky barrier diode according to claim 1, wherein the raised diffusion guard ring comprises a heavily-doped diffusion guard ring, a moderately-doped diffusion guard ring or a heavily-doped diffusion guard ring formed within a moderately-doped diffusion guard ring.

4. The LOCOS Schottky-based barrier diode according to claim 1, wherein the raised diffusion guard ring is formed in a self-aligned manner by implanting doping impurities across a pad oxide layer into a surface portion of the lightly-doped epitaxial semiconductor layer between the outer LOCOS field oxide layer and the inner LOCOS field oxide layer.

5. The LOCOS-based Schottky barrier diode according to claim 1, wherein the raised diffusion guard ring is formed in a self-aligned manner by a thermal diffusion process using a liquid source, a solid source or a gas source through a diffusion window formed between the outer LOCOS field oxide layer and the inner LOCOS field oxide layer.

6. The LOCOS-based Schottky barrier diode according to claim 1, wherein the metal silicide layer comprises a refractory metal silicide layer formed by a self-aligned silicidation process.

7. The LOCOS-based Schottky barrier diode according to claim 1, wherein a compensated implantation of the second conductivity type is performed to form a compensated diffusion layer in a surface portion of the lightly-doped epitaxial semiconductor layer under the outer and inner LOCOS field oxide layers.

8. A LOCOS-based Schottky barrier diode, comprising:
a semiconductor substrate of a first conductivity type, wherein the semiconductor substrate comprises a lightly-doped epitaxial silicon layer being formed in a heavily-doped silicon substrate;
a diffusion guard ring region being formed between an outer LOCOS field oxide layer and an inner LOCOS field oxide layer by using a local oxidation of silicon (LOCOS) process, wherein the diffusion guard ring region is doped in a self-aligned manner to form a raised diffusion guard ring of a second conductivity type in a surface portion of the lightly-doped epitaxial silicon layer;
a recessed semiconductor substrate being formed by removing the inner LOCOS field oxide layer;
a refractory metal silicide layer being formed over an inner portion of the raised diffusion guard ring surrounded by the outer LOCOS field oxide layer and the recessed semiconductor substrate surrounded by the raised diffusion guard ring; and
a patterned metal layer being at least formed over the refractory metal silicide layer.

9. The LOCOS-based Schottky barrier diode according to claim 8, wherein the lightly-doped epitaxial silicon layer has a doping concentration between 10¹⁴/cm³ and 10¹⁷/cm³ and a thickness between 2 μm and 35 μm.

10. The LOCOS-based Schottky barrier diode according to claim 8, wherein the outer and inner LOCOS field oxide layers being formed by the local oxidation of silicon (LOCOS) process are grown in a steam or wet oxygen ambient to have a thickness between 6000 Angstroms and 10000 Angstroms.

11. The LOCOS-based Schottky barrier diode according to claim 8, wherein the raised diffusion guard ring comprises a heavily-doped diffusion guard ring, a moderately-doped diffusion guard ring or a heavily-doped diffusion guard ring formed within a moderately-doped diffusion guard ring.

12. The LOCOS-based Schottky barrier diode according to claim 8, wherein a compensated diffusion layer is formed in a surface portion of the recessed semiconductor substrate by implanting doping impurities of the second conductivity type across a pad oxide layer into a surface portion of the lightly-doped epitaxial silicon layer outside of the diffusion guard ring region before performing the local oxidation of silicon process.

13. The LOCOS-based Schottky barrier diode according to claim 8, wherein the patterned metal layer comprising a metal layer on a barrier metal layer is formed over a portion of a patterned capping dielectric layer and the metal silicide layer.

14. A LOCOS-based Schottky barrier diode, comprising:
a semiconductor substrate of a first conductivity type, wherein the semiconductor substrate comprises a lightly-doped epitaxial silicon layer being formed on a heavily-doped silicon substrate;
a diffusion guard ring region being formed between an outer LOCOS field oxide layer and an inner LOCOS field oxide layer by using a local oxidation of silicon (LOCOS) process in a steam or wet oxygen ambient, wherein the diffusion guard ring region is doped in a self-aligned manner by using ion implantation or a thermal diffusion process to form a raised diffusion guard ring of a second conductivity type in a surface portion of the lightly-doped epitaxial silicon layer;
a recessed semiconductor substrate being formed by removing the inner LOCOS field oxide layer, wherein the recessed semiconductor substrate comprises a compensated diffusion layer being formed in a surface portion of the lightly-doped epitaxial silicon layer;
a refractory metal silicide layer being formed over an inner portion of the raised diffusion guard ring surrounded by the outer LOCOS field oxide layer and the recessed semiconductor substrate surrounded by the raised diffusion guard ring, wherein the refractory metal silicide layer is formed by a self-aligned silicidation process; and
a patterned metal layer being at least formed over a portion of a patterned capping dielectric layer and the refractory metal silicide layer.

15. The LOCOS-based Schottky barrier diode according to claim 14, wherein the patterned capping dielectric layer being comprised of silicon nitride is formed over an outer portion of a thermal oxide layer formed on the raised diffusion guard ring and a portion of the outer LOCOS field oxide layer.

16. The LOCOS-based Schottky barrier diode according to claim 14, wherein the thermal diffusion process comprises a thermal doping process using a liquid source, a solid source or a gas source.

17. The LOCOS-based Schottky barrier diode according to claim 14, wherein the diffusion guard ring region is formed by patterning a masking silicon nitride layer on a pad oxide layer using a first masking photoresist step.

18. The LOCOS-based Schottky barrier diode according to claim 14, wherein the inner LOCOS field oxide layer is removed after doping the raised diffusion guard ring by using a second masking photoresist step.

19. The LOCOS-based Schottky barrier diode according to claim 14, wherein the patterned metal layer comprising a silver (Ag), aluminum (Al) or gold (Au) layer on a barrier metal layer is formed over a portion of the patterned capping dielectric layer and the refractory metal silicide layer using a third masking photoresist step.

20. The LOCOS-based Schottky barrier diode according to claim 14, wherein the compensated diffusion layer is formed by implanting doping impurities of the second conductivity type across a pad oxide layer into surface portions of the lightly-doped epitaxial silicon layer outside of the diffusion guard ring region before performing the local oxidation of silicon process.
